(19) United States
(12) Patent Application Publication
(10) Pub. No.: US 2008/0253588 A1
(43) Pub. Date: Oct. 16, 2008

(54) DIGITAL VOLUME CONTROLLER AND CONTROL METHOD THEREOF

(75) Inventors: Yao-Kun Tsai, Taipei City (TW); Shen-Fu Lai, Taipei City (TW); Jia-Shiung Guo, Taipei City (TW)

Correspondence Address: J C PATENTS, INC., 4 VENTURE, SUITE 250, IRVINE, CA, 92618, US

(73) Assignee: INVENTEC CORPORATION, Taipei (TW)

(21) Appl. No.: 11/848,882

(22) Filed: Aug. 31, 2007

(30) Foreign Application Priority Data
Apr. 14, 2007 (TW) 96113186

(51) Int. Cl. H03G 3/00

(52) U.S. Cl. 381/109

(57) ABSTRACT

A digital volume controller and a control method thereof are provided. The digital volume controller includes an adjuster, a D flip-flop and a processor. The adjuster outputs a first signal and a second signal according to a rolling direction of the adjuster. There is a phase difference between the first signal and the second signal. The D flip-flop includes a clock terminal coupled to the first signal, a D terminal coupled to the second terminal and a Q terminal coupled to a third signal. When the first signal generates an enabling trigger, the processor generates a volume control signal according to a logic level of the third signal.

### CROSS-REFERENCE TO RELATED APPLICATION

This application claims the priority benefit of Taiwan application serial no. 96113186, filed Apr. 14, 2007. All disclosure of the Taiwan application is incorporated herein by reference.

### BACKGROUND OF THE INVENTION

1. Field of the Invention

The present invention generally relates to volume controller, and more particularly to a digital volume controller for a notebook computer.

2. Description of Related Art

With the advent of the digital age, consumers are paying more attention to audio and video functions in the notebook computers. Audio volume of current a notebook computer is typically controlled by software, which is inconvenient to users. As a solution, variable resistors are employed by some notebook computers for adjusting audio volume. However, adjustments of the audio volume by analogue approaches, e.g., variable resistors, and by software are substantially independent to each other. Therefore, the user has to adjust the variable resistor and an interface of the software respectively for obtaining a maximum volume. Further, the variable resistor can be rotated for limited rounds or scale, and after long time usage, there is a risk of failure due to poor contact.

Volume controls by software and hardware can be incorporated together in a digital volume control method, by which the user can totally control the volume by operating an external knob or roller, instead of operating software and hardware, e.g., the external knob or roller, individually. In other words, when the user turns a volume control knob, the volume of the software is correspondingly adjusted. Therefore, the user can control the knob or roller, or a software interface to adjust the speaker to obtain the maximum or minimum audio volume.

However, the current digital volume control systems for notebook computers are not popular, and the application technologies are not yet well developed. Therefore, the development of a cheap, slim, and convenient digital volume control system becomes a concern of the manufacturers.

### SUMMARY OF THE INVENTION

Accordingly, the present invention is directed to a digital volume controller, in which a digital variable resistor is employed as a roller for digital volume adjustment, incorporating with a D flip-flop and an embedded controller for processing and determining a signal so as to output a corresponding volume control signal to the operation system, and thus performing a direct volume control of the software.

The present invention is also directed to a digital volume control method, in which a volume control signal is generated according to a phase difference outputted from the digital variable resistor, and the operation system perform a direct digital volume control according to the volume control signal.

The present invention provides a digital volume controller. The digital volume controller includes an adjuster, a D flip-flop, and a processor. The adjuster alternatively outputs a first signal and a second signal depending on a turning direction thereof. There is a phase difference between the first signal and the second signal. The D flip-flop includes a clock terminal coupled to the first signal, a D terminal coupled to the second signal, and a Q terminal outputting a third signal. The processor is coupled to the Q terminal of the D flip-flop. When the first signal generates an enabling trigger, the processor generates a volume control signal according to a logic level of the third signal.

According to an embodiment of the present invention, the foregoing adjuster at least includes a first output terminal, a second output terminal and a common terminal. The first output terminal outputs the first signal, and the second output terminal outputs the second signal. The common terminal is coupled to the ground.

According to an embodiment of the present invention, the foregoing digital volume controller further includes a first resistor, a second resistor, a capacitor, and an electrostatic discharge (ESD) protection device. The first resistor is coupled between the first output terminal and the clock terminal of the D flip-flop. The second resistor is coupled between an operation voltage and the clock terminal of the D flip-flop. The capacitor is coupled between the clock terminal of the flip-flop and a ground. The ESD protection device is coupled between the first output terminal and the ground. There is similar circuit structure between the second output terminal of the adjuster and the D terminal of the D flip-flop.

According to an embodiment of the present invention, the foregoing adjuster is a digital variable resistor (VR) having a roller; and the processor is an embedded controller.

According to an embodiment of the present invention, when the first signal generates an enabling trigger, if the third signal is a logic high level, the volume control signal is a volume increase signal; and if the third signal is a logic low level, the volume control signal is a volume decrease signal. The foregoing enabling trigger can be either a positive edge trigger, or a negative edge trigger.

The present invention is also directed to a digital volume control method suitable for the foregoing digital volume controller. The digital volume control method may be described as follows. First, a first signal is used to trigger a D flip-flop for latching up a second signal and output a third signal. Next, whether or not the first signal generates an enabling trigger is determined, wherein if the first signal generates an enabling trigger, a volume control signal is generated according to a logic level of the third signal. Other details about the volume control method can be learnt by referring to the foregoing description of the digital controller, and the description will not be repeated here.

The present invention provides a novel circuit structure of a digital volume controller for notebook computers, in which adjustment information of a roller or a knob can be converted to digital signals by a D flip-flop and an embedded controller, so as to directly adjusting a volume set value of an operation system. The present invention incorporates a user interface and the operation system by conversion of the digital signals, which not only improves audio quality thereof, but also improves convenience of volume adjustment.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B show diagrams illustrating a digital variable resistor according to a first embodiment of the present invention.

FIGS. 2A and 2B show signal waveforms of the digital variable resistor of the first embodiment of the present invention.

FIG. 3 is a circuit diagram of a digital volume controller according to the first embodiment of the present invention.

FIGS. 4A and 4B are signal waveforms of the digital volume controller of the first embodiment of the present invention.

FIG. 5 is a flow chart illustrating a digital volume control method suitable for the digital volume controller according to a second embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

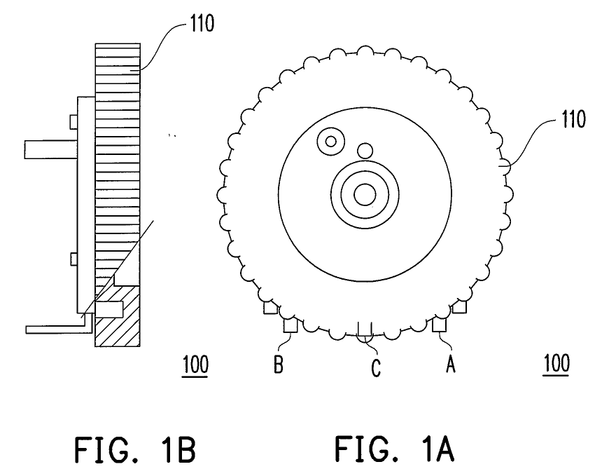

FIGS. 1A and 1B show diagrams illustrating a digital variable resistor according to a first embodiment of the present invention. As shown in FIG. 1A, the present invention employs a digital variable resistor as a volume adjuster 100. Referring to FIG. 1A, the digital variable resistor includes a roller, which can be disposed on, for example a lateral side of a notebook computer. A user may adjust a volume by rolling the roller. The adjuster 100 at least includes a first output terminal A, a second output terminal B and a common terminal C, as shown in FIG. 1B. When the user rolls or slides the roller 110, the adjuster 100 outputs a first signal A via the first output terminal A, and a second signal via the second output terminal B. The common terminal C provides a common level, and is coupled to a ground GND. In this manner, the first signal S1 is a voltage difference between the first output terminal A and the common terminal C, and the second signal S2 is a voltage difference between the second output terminal B and the common terminal C.

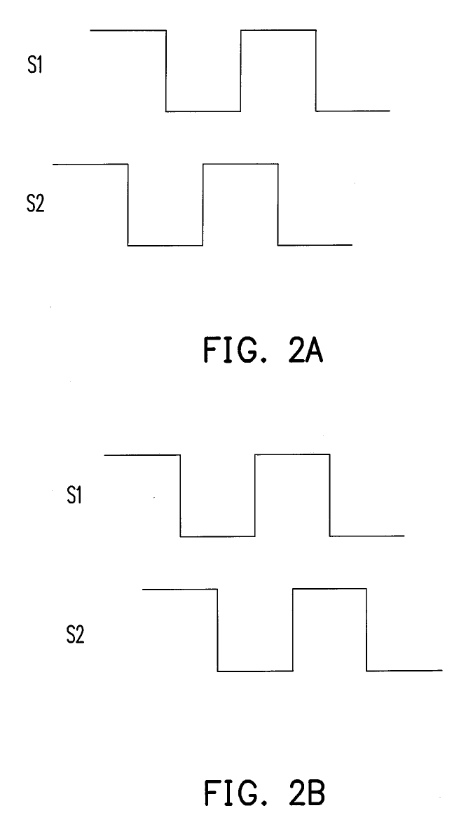

As the adjuster is turned towards different directions, a phase difference of the first signal S1 and the second signal S2 varies. When the adjuster 100 is turned leftward, the first signal S1 drops behind the second signal S2, as shown in FIG. 2A; and when the adjuster 100 is turned rightward, the first signal S1 stays ahead the second signal S2 as shown in FIG. 2B. As such, the rolling direction of the adjuster 100, corresponding to the intention of the user to increase or decrease the volume, can be learnt by determining the phase difference between the first signal S1 and the second signal S2. The adjuster 100 is only a volume controller of a user interface. It is exemplarily illustrated hereby with a roller shaped digital variable resistor. However, the shape or the type of the adjuster is not intended to be limited according to the present invention.

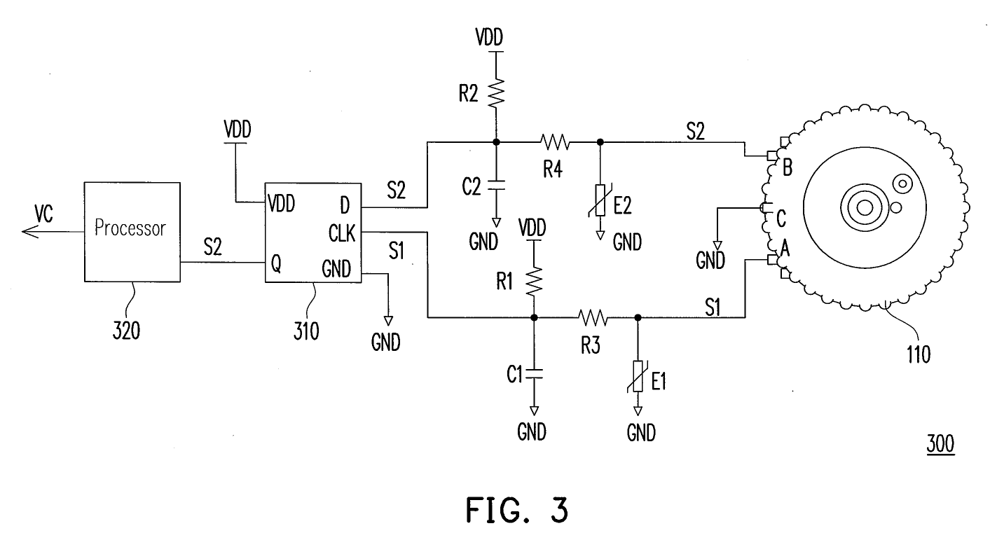

FIG. 3 is a circuit diagram of a digital volume controller 300 according to the first embodiment of the present invention. The digital volume controller 300 includes an adjuster 100, a D flip-flop 310, and a processor 320. The digital volume controller 300 further includes resistors R1 through R4, capacitors C1 and C2, and ESD protection devices E1 and E2 coupled between the first signal S1, the second signal S2 and the D flip flop 310. The resistor R3 is coupled between a first output terminal A and a clock terminal CLK of the D flip-flop 310. The resistor R1 is coupled between an operation voltage VDD and the clock terminal CLK of the D flip-flop. The capacitor C1 is coupled between the clock terminal CLK and a ground GND of the D flip-flop. The resistor R4 is coupled between the second output terminal B and a D terminal of the D flip-flop. The resistor R2 is coupled between the operation voltage VDD and the D terminal of the D flip-flop. The ESD protection devices E1 and E2 are coupled between the first output terminal A, the second output terminal B and the ground GND, respectively, for reducing ESD damage.

The first signal S1 may be transmitted to the clock terminal CLK of the flip-flop 310 via the resistor R3, and the second signal S2 may be transmitted to the D terminal of the flip-flop 310 via the resistor R4. In the current embodiment, the D flip-flop 310 is a positive edge triggered flip-flop. When the first signal S1 generates a positive edge trigger, the D flip-flop outputs a logic condition of the second signal S2 to the Q terminal and generates a third signal S3. When the first signal S1 enables, the processor 320 generates a volume control signal VC according to a logic level of the third signal S3. Whether or not the first signal S1 enables may be determined by the processor 320, or by providing another detecting circuit to detect a logic level of the first signal S1.

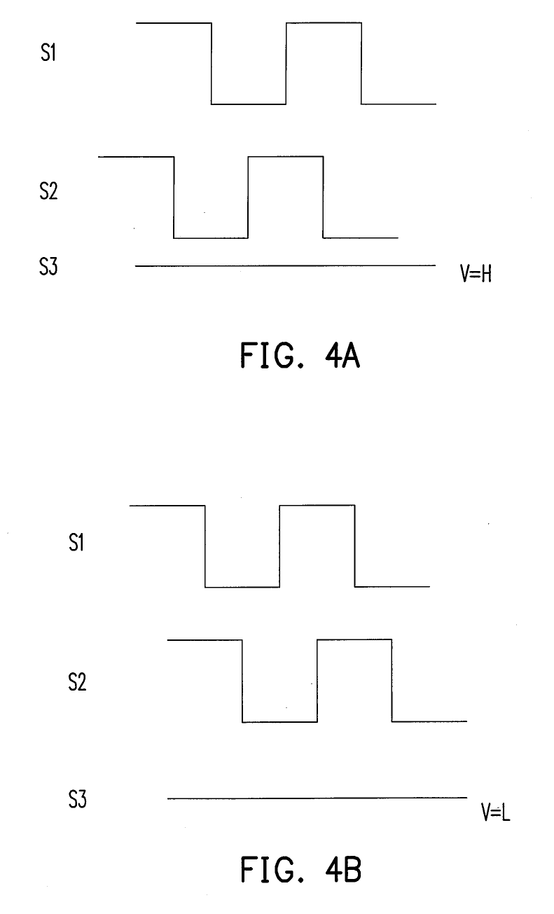

The waveforms and the relationship thereof of the first signal S1, the second signal S2, and the third signal S3, are shown in FIGS. 4A and 4B. FIG. 4A is a signal waveform illustrating the situation of the roller 110 rolling leftwards. According to the embodiment, the D flip-flop is positive edge triggered. When the first signal S1 generates a positive edge trigger, i.e., converting from a logic low level to a logic high level, the second signal S2 is maintained at a logic high level, so that the third signal S3 outputted from the Q terminal of the D flip-flop 310 is maintained at a logic high level. Therefore, in such a condition, the volume control signal VC is a volume increase signal, according to which the operation system increases the volume. Otherwise, when the roller rolls rightwards, the third signal V3 is maintained at a logic low level. Accordingly, the volume control signal VC is a volume decrease signal, according to which the operation system decreases the volume.

The processor 320 keeps detecting a variation of the voltage level of the first signal S1. When the first signal S1 generates an enabling trigger (negative edge trigger hereby), the processor 320 generates a volume control signal VC according to the logic level of the third signal S3. The volume control signal VC can be either directly applied to a speaker for volume adjustment or outputted to the operations system so as to adjust the volume by software. In other words, the processor 320 determines the direction of the roller 110 being rolled by the user according to the logical level of the first signal S1, and thus determining whether the user increases or decreases the volume, so as to control the volume via the operation system.

Relationship between the logic level of the third signal S3 and the volume adjusting direction, i.e., increase or decrease, can be set by the processor 320. That is, it can also be set such that the rolling of the roller rightwards increases the volume and rolling of the roller leftwards decreases the volume. According to an embodiment of the present invention, the processor 320 can be substituted by an embedded controller, or directly integrated to the notebook computer, in that an audio chip or a computer processing unit is employed to control the volume of the notebook. However, it is should be noted that regardless of the foregoing approaches, it must be incorporated with the operation system, in that when the volume is adjusted by the roller 110, volume output of the operations system is adjusted. In this way, the user may achieve digital volume control and adjust the volume to the maximum or minimum by controlling the roller 110.

According to another embodiment of the present invention, the D flip-flop 310 may also be negative edge triggered, and the enabling trigger of the first signal may also be a positive edge trigger. This causes a distinction of relationship between the logic level of the third signal S3 and the rolling direction of the adjuster 100. Those of ordinary skill in the art may deduce other solutions by referring to the teachings of the present invention.

### Second Embodiment

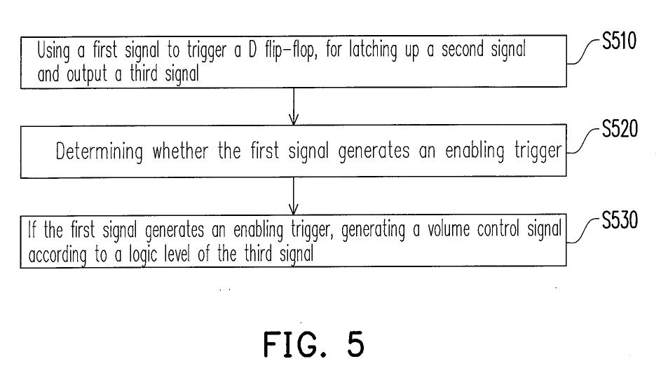

The present invention is also directed to a digital volume control method suitable for the foregoing digital volume controller. The digital volume controller includes a roller for outputting a first signal and a second signal according to a turning direction thereof. There is a phase difference between the first signal and the second signal. The digital volume control method, as shown in FIG. 5, includes the following steps. First, at step S510, a first signal is used to trigger a D flip-flop for latching up a second signal and outputting a third signal. Next, at step S520, whether or not the first signal generates an enabling trigger is determined. Next, at step S530, when the first signal generates an enabling trigger, a volume control signal is generated according to a logic level of the third signal.

At step 530, when the first signal generates an enabling trigger, if the third signal is a logic high level, then the volume control signal is a volume increase signal; or if the third signal is a logic low level, then the volume control signal is a volume decrease signal. The enabling trigger of the foregoing first signal may be a positive edge trigger or a negative edge trigger.

In summary, the present invention converts the adjustment signal of the roller or the knob into a digital signal, via which the operation system directly perform a digital volume adjustment. The present invention can be integrated into the notebook and function as a controller of the digital volume adjustment. Because of the present invention controls volume using digital signal, is the extent of rolling not limited. Furthermore, the risk of poor contact caused due to long time usage, or device consumption may be avoided, and the convenience of volume adjustment is accordingly improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A digital volume controller, comprising:
an adjuster, for outputting a first signal and a second signal according to a turning direction thereof, wherein there is a phase difference between the first signal and the second signal; and
a D flip-flop, comprising a clock terminal coupled to the first signal, a D terminal coupled to the second signal and a Q terminal for outputting a third signal; and
a processor, coupled to the Q terminal of the D flip-flop, wherein when the first signal generates an enabling trigger, the processor generates a volume control signal according to a logic level of the third signal.

2. The digital volume controller of claim 1, wherein the adjuster comprises a first output terminal, a second output terminal and a common terminal, wherein the first output terminal outputs the first signal; the second output terminal outputs the second signal; and the common terminal is coupled to the ground.

3. The digital volume controller of claim 2, wherein the digital volume controller comprises:
a first resistor, coupled between the first output terminal and the clock terminal of the D flip-flop;
a second resistor, coupled between an operation voltage and the clock terminal of the D flip-flop;
a capacitor, coupled between the clock terminal of the D flip-flop and the ground; and
an electrostatic discharge protection device, coupled between the first output terminal and the ground.

4. The digital volume controller of claim 2, wherein the digital volume controller comprises:
a first resistor, coupled between the second output terminal and the D terminal of the D flip-flop;
a second resistor, coupled between an operation voltage and the D terminal of the D flip-flop;
a capacitor, coupled between the D terminal of the D flip-flop and the ground; and
an electrostatic discharge protection device, coupled between the second output terminal and the ground.

5. The digital volume controller of claim 1, wherein the adjuster is a digital variable resistor.

6. The digital volume controller of claim 1, wherein the processor is an embedded controller.

7. The digital volume controller of claim 1, wherein the adjuster comprises a roller.

8. The digital volume controller of claim 1, wherein when the first signal generates an enabling trigger, the volume control signal is a volume increase signal when the third signal is a logic high level.

9. The digital volume controller of claim 1, wherein the volume control signal is a volume decrease signal when the third signal is a logic low level.

10. The digital volume controller of claim 1, wherein the enabling trigger is either a positive edge trigger or a negative edge trigger.

11. A digital volume control method, suitable for a digital volume controller, wherein the digital volume controller comprises a roller for outputting a first signal and a second signal according to a turning direction thereof, wherein there is a phase difference between the first signal and the second signal, the digital volume control method comprising:
using the first signal to trigger a D flip-flop for latching up the second signal and output a third signal;
determining whether the first signal generates an enabling trigger; and
generating a volume control signal according to a logic level of the third signal when the first signal generates an enabling trigger.

12. The digital volume control method of claim 11, wherein when the third signal is a logic high level, the volume control signal is a volume increase signal.

13. The digital volume control method of claim 11, wherein when the third signal is a logic low level, the volume control signal is a volume decrease signal.

14. The digital volume control method of claim 11, wherein the enabling trigger is either a positive edge trigger or a negative edge trigger.
